(19) United States
(12) Patent Application Publication
(10) Pub. No.: US 2022/0139759 A1
(43) Pub. Date: May 5, 2022

(54) SUBSTRATE HOLDER, SUBSTRATE TRANSFER DEVICE, AND METHOD OF MANUFACTURING SUBSTRATE HOLDER

(71) Applicant: Tokyo Electron Limited, Tokyo (JP)

(72) Inventor: Wataru MATSUMOTO, Nirasaki City (JP)

(21) Appl. No.: 17/452,642

(22) Filed: Oct. 28, 2021

(30) Foreign Application Priority Data
Nov. 5, 2020 (JP) 2020-184955

(51) Int. Cl. H01L 21/687; H01L 21/67; H01L 21/677

(52) U.S. Cl. CPC H01L 21/68735; H01L 21/4807; H01L 21/67742; H01L 21/67017

(57) ABSTRACT

There is provided a substrate holder. The substrate holder that holds a substrate and is installed in a device for transferring the substrate. The substrate holder includes: a ceramic main body; and a heat pipe which includes a flow path of a working fluid. The flow path is formed inside the main body.

### CROSS-REFERENCE TO RELATED APPLICATION

This application is based upon and claims the benefit of priority from Japanese Patent Application No. 2020-184955, filed on Nov. 5, 2020, the entire contents of which are incorporated herein by reference.

### TECHNICAL FIELD

The present disclosure relates to a substrate holder, a substrate transfer device, and a method of manufacturing the substrate holder.

### BACKGROUND

Patent Document 1 discloses a transfer mechanism for loading/unloading a wafer in/from a processing apparatus that subjects the wafer to heat treatment in a process container. The transfer mechanism includes an arm portion having arms and capable of bending/stretching and turning, and a fork portion connected to the base end of the arm portion and holding the wafer. The fork portion is made of a ceramic material.

### PRIOR ART DOCUMENTS

### Patent Documents

Japanese laid-open publication No. 2011-187910

### SUMMARY

According to one embodiment of the present disclosure, there is provided a substrate holder that holds a substrate and is installed in a device for transferring the substrate. The substrate holder includes: a ceramic main body; and a heat pipe including a flow path of a working fluid formed inside the main body.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plane view showing the outline of the configuration of a wafer processing system.

FIG. 2 is a perspective view showing the outline of the configuration of a wafer transfer device.

FIG. 3 is a cross-sectional view showing the outline of the internal configuration of a fork.

FIG. 4 is a longitudinal sectional view showing the outline of the internal configuration of the fork.

FIGS. 5A to 5D are explanatory views showing a method of manufacturing a fork.

FIGS. 6A and 6B are explanatory views showing a method of forming a heat pipe in the fork manufacturing method.

FIGS. 7A and 7B are explanatory views showing a method of forming a heat pipe in another embodiment.

FIGS. 8A and 8B are explanatory views showing a method of forming a heat pipe in another embodiment.

FIGS. 9A and 9B are explanatory views showing a method of forming a heat pipe in another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, various processes such as a film forming process and an etching process are performed on a semiconductor wafer (substrate; hereinafter referred to as a “wafer”) in a reduced pressure atmosphere (vacuum atmosphere). For example, when plural types of processes are performed in single-wafer process modules, a so-called cluster-type wafer processing system is used in which process modules are connected to each other via gate valves around a transfer module having a transfer device therein. Then, the transfer device is used to transfer a wafer in the transfer module sequentially toward the process modules, so that the wafer is sequentially subjected to desired processes.

Here, when the plurality of processes is performed in one wafer processing system, the processing temperatures of the processes may be different from each other. For example, a film forming process is a high-temperature process, whereas an etching process is a low-temperature process. Then, for example, in the transfer mechanism (transfer device) disclosed in Patent Document 1, a ceramic material having heat resistance suitable for a high-temperature process is used for the fork portion (fork) that supports the wafer, so that the wafer subjected to either the high-temperature process and the low-temperature process can be supported.

However, when the processes with different processing temperatures are performed in this way, since it is difficult to transfer the wafer at an appropriate temperature by the transfer device, various effects may occur. For example, when the wafer is loaded/unloaded in/from a process module (high-temperature chamber) for a high-temperature process, the temperature of the fork holding the wafer in the transfer device rises due to the temperature from the wafer and the radiant heat from the process module. In this state, when the wafer is loaded/unloaded in/from a process module (low-temperature chamber) for a low-temperature process, since the wafer before the low-temperature process is loaded in the low-temperature chamber in a state where the wafer is excessively heated, the process rate may deviate from a desired rate. Further, since a temperature difference occurs between the wafer before the low-temperature process and the wafer after the low-temperature process, damage or cracks to the wafer may occur.

Therefore, there is room for improvement in the conventional transfer device, and it is desired to appropriately control the temperature of the fork of the transfer device.

The technique according to the present disclosure appropriately adjusts the temperature of a substrate holder in a substrate transfer device. Hereinafter, a wafer transfer device as the substrate transfer device, a fork as the substrate holder, and a method of manufacturing the fork according to an embodiment of the present disclosure will be described with reference to the drawings. Through the present disclosure and the drawings, elements having substantially the same functional configuration are denoted by the same reference numerals, and therefore, explanation thereof will not be repeated.

### <Configuration of Wafer Processing System>

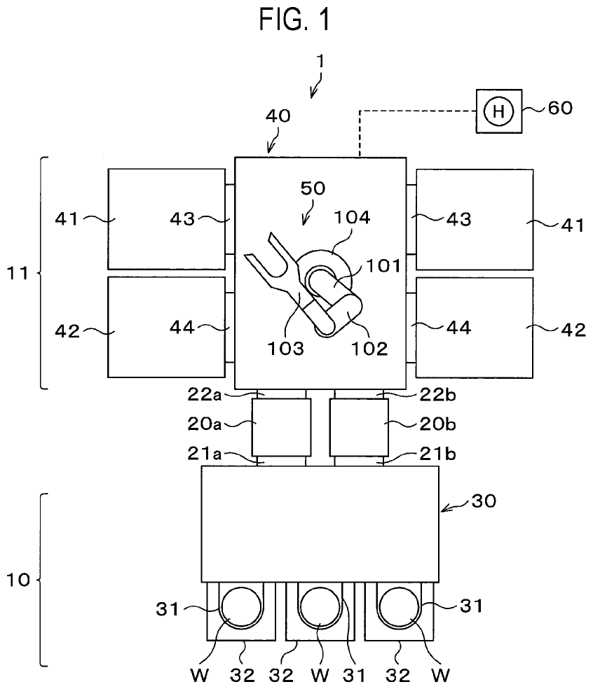

First, the configuration of a wafer processing system including a wafer transfer device according to the present embodiment will be described. FIG. 1 is a plane view showing the outline of the configuration of the wafer processing system. In the present embodiment, a case where a wafer processing system 1 includes various process modules for performing a film forming process and an etching process on a wafer W as a substrate will be described. The configuration of the wafer processing system 1 of the present disclosure is not limited thereto, but may be arbitrarily selected.

As shown in FIG. 1, the wafer processing system 1 has a configuration in which the normal pressure part 10 and the decompression part 11 are integrally connected via load lock modules 20a and 20b. The normal pressure part 10 loads/unloads a hoop 31, which will be described later, capable of accommodating the wafers W in a normal pressure atmosphere (air atmosphere), and transfers the wafer W to and from the load lock modules 20a and 20b. The decompression part 11 performs a process on the wafer W under a decompression atmosphere (vacuum atmosphere), and transfers the wafer W to and from the load lock modules 20a and 20b.

The load lock module 20a temporarily holds the wafer W in order to deliver the wafer W, which is transferred from a loader module 30 (which will be described later) of the normal pressure part 10, to a transfer module 40 (which will be described later) of the decompression part 11.

The load lock module 20a is connected to the loader module 30 (which will be described later) via a gate valve 21a. Further, the load lock module 20a is connected to the transfer module 40 (which will be described later) via a gate valve 22a. The airtightness and communication between the load lock module 20a, the loader module 30, and the transfer module 40 are compatible with each other by the gate valves 21a and 22a.

A gas supply part (not shown) for supplying a gas and an exhaust part (not shown) for discharging a gas are connected to the load lock module 20a, and the interior of the load lock module 20a is configured to be able to switch between the normal pressure atmosphere and the decompression atmosphere by the gas supply part and the exhaust part. That is, the load lock module 20a is configured to be able to appropriately deliver the wafer W between the normal pressure part 10 of the normal pressure atmosphere and the decompression part 11 of the decompression atmosphere.

The load lock module 20b has the same configuration as the load lock module 20a. That is, the load lock module 20b has a gate valve 21b near the loader module 30 and a gate valve 22b near the transfer module 40.

The number and arrangement of load lock modules 20a and 20b are not limited to the present embodiment and can be arbitrarily set.

The normal pressure part 10 has the loader module 30 provided with a wafer transfer device (not shown), and a load port 32 on which a hoop 31 capable of storing the wafers W is placed. The loader module 30 is also referred to as an EFEM (Equipment Front End Module).

The loader module 30 has a rectangular housing therein, and the interior of the housing is maintained at the normal pressure atmosphere. Load ports 32, for example, three load ports 32, are arranged side by side on one side surface forming the long side of the housing of the loader module 30. The load lock modules 20a and 20b are arranged side by side on the other side surface forming the long side of the housing of the loader module 30. Further, the loader module 30 has the wafer transfer device (not shown) that can move in the longitudinal direction inside the housing. The wafer transfer device can transfer the wafer W between the hoop 31 placed on the load port 32 and the load lock modules 20a and 20b.

The number and arrangement of load ports 32 are not limited to the present embodiment and can be arbitrarily designed. Further, the normal pressure part 10 may be provided with a process module for performing a desired process on the wafer W under the normal pressure atmosphere, for example, a module for performing a process for adjusting the horizontal orientation of the wafer W.

The hoop 31 accommodate the wafers W, for example, 25 wafers W per lot, so as to be stacked in multiple stages at equal intervals. Further, the interior of the hoop 31 placed on the load port 32 is filled and sealed with, for example, the air or a nitrogen gas.

The decompression part 11 includes the transfer module 40 for transferring the wafer W to various process modules, a film forming module 41 as a processing apparatus for performing a film forming process on the wafer W, and an etching module 42 as a processing apparatus for performing an etching process on the wafer W. The interiors of the transfer module 40, the film forming module 41, and the etching module 42 are each maintained at the decompression atmosphere. Film forming modules 41 and etching modules 42, for example, two film forming modules 41 and two etching modules 42, are provided for the transfer module 40. The transfer module 40 is also referred to as a VTM (Vacuum Transfer Module).

Further, the film forming module 41 and the etching module 42 are connected to the transfer module 40 via gate valves 43 and 44, respectively. The airtightness and communication between the transfer module 40, the film forming module 41, and the etching module 42 is compatible to each other by the gate valves 43 and 44.

The number and arrangement of processing modules provided in the transfer module 40 and the type of process are not limited to the present embodiment and can be arbitrarily set.

The transfer module 40 has a rectangular housing therein and is connected to the load lock modules 20a and 20b via the gate valves 22a and 22b, as described above. The transfer module 40 transfers the wafer W loaded in the load lock module 20a to one film forming module 41 and one etching module 42 sequentially to perform the film forming process and the etching processing, and then unloads it to the normal pressure part 10 via the load lock module 20b.

A wafer transfer device 50 for transferring the wafer W is provided inside the transfer module 40. The detailed configuration of the wafer transfer device 50 will be described later.

A control part 60 is provided in the above wafer processing system 1. The control part 60 is, for example, a computer including a CPU, a memory, or the like and has a program storage part (not shown). The program storage part stores a program that controls the processing of the wafer W in the wafer processing system 1. The program may be recorded on a computer-readable storage medium H and may be installed on the control part 60 from the storage medium H.

### <Wafer Processing in Wafer Processing System>

The wafer processing system 1 according to the present embodiment is configured as described above. Next, the wafer processing in the wafer processing system 1 will be described.

First, the hoop 31 containing the wafers W is placed on the load port 32.

Next, the wafer W is taken out from the hoop 31 by the wafer transfer device (not shown) and is loaded in the load lock module 20a. After the wafer W is loaded in the load lock module 20a, the gate valve 21a is closed to seal and decompress the interior of the load lock module 20a. After that, the gate valve 22a is opened to communicate the interior of the load lock module 20a with the interior of the transfer module 40.

Next, when the load lock module 20a and the transfer module 40 communicate with each other, the wafer W is taken out by the wafer transfer device 50 and is loaded in the transfer module 40 from the load lock module 20a.

Next, the gate valve 43 is opened to load the wafer W in the film forming module 41 by the wafer transfer device 50. Subsequently, the gate valve 43 is closed, and the film forming process is performed on the wafer W. When the film forming process is completed, the gate valve 43 is opened to unload the wafer W from the film forming module 41 by the wafer transfer device 50. Then, the gate valve 43 is closed.

Next, the gate valve 44 is opened to load the wafer W in the etching module 42 by the wafer transfer device 50. Subsequently, the gate valve 44 is closed, and the etching process is performed on the wafer W. When the etching process is completed, the gate valve 44 is opened to unload the wafer W from the etching module 42 by the wafer transfer device 50. Then, the gate valve 44 is closed.

Next, the gate valve 22b is opened, and the wafer W is loaded in the load lock module 20b by the wafer transfer device 50. After the wafer W is loaded in the load lock module 20b, the gate valve 22b is closed to seal the interior of the load lock module 20b and open to the atmosphere.

Next, two wafers W are returned to and accommodated in the hoop 31 by the wafer transfer device (not shown). In this way, a series of wafer processing in the wafer processing system 1 is completed.

### <Configuration of Wafer Transfer Device>

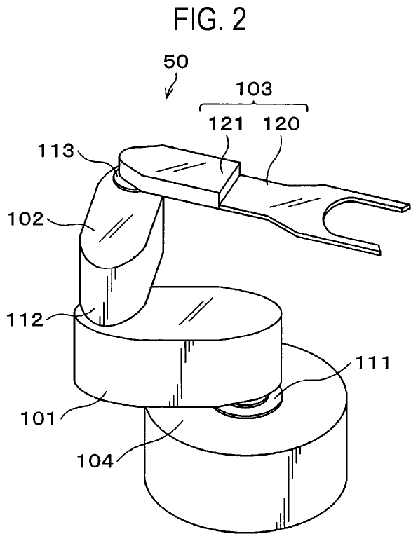

Next, the configuration of the above-described wafer transfer device 50 will be described. FIG. 2 is a perspective view showing the outline of the configuration of the wafer transfer device 50.

As shown in FIG. 2, the wafer transfer device 50 is an articulated robot and has arms, for example, three arms 101, 102, and 103. The arms 101, 102, and 103 are supported by a transfer base 104.

The base end of the first arm 101 is connected to the transfer base 104, and the tip end thereof is connected to the second arm 102. The base end of the second arm 102 is connected to the first arm 101, and the tip end thereof is connected to the third arm 103. The base end of the third arm 103 is connected to the second arm 102.

A first joint 111 is installed between the base end of the first arm 101 and the transfer base 104. A second joint 112 is installed between the base end of the second arm 102 and the tip end of the first arm 101. A third joint 113 is provided between the base end of the third arm 103 and the tip end of the second arm 102. Drive mechanisms (not shown) are installed inside the joints 111, 112, and 113, respectively. By these drive mechanism, the arms 101, 102, and 103 are configured to be able to rotate (turn) around the joints 111, 112, and 113, respectively.

A hollow portion having the normal pressure atmosphere is formed inside each of the first arm 101 and the second arm 102. A temperature adjusting mechanism (not shown) for adjusting each of the first arm 101 and the second arm 102 to a desired temperature is accommodated in each hollow portion. A known mechanism can be arbitrarily selected and used as the temperature adjusting mechanism. For example, the temperature can be adjusted by supplying dry air to the hollow portion.

In addition to the temperature adjusting mechanism, various parts are accommodated in each hollow portion. For example, a cable (not shown) for transmitting power to the drive mechanism of the joints 111, 112, and 113 is accommodated in each hollow portion.

The third arm 103 has a fork 120 (an end effector) as a substrate holding part, and a hand part 121 that supports the fork 120. The fork 120 is installed on the tip end side of the third arm 103 and holds the wafer W. The hand part 121 is installed on the base end side of the third arm 103 and is attached to the third joint 113.

In the present embodiment, the fork 120 is configured to be able to be vertically moved by the drive mechanism of the transfer base 104 and is further configured to be able to be horizontally moved by the drive mechanism of the joints 111, 112, and 113. That is, in the present embodiment, the transfer base 104 and the joints 111, 112, and 113 constitute a moving mechanism in the present disclosure.

### <Configuration of Fork>

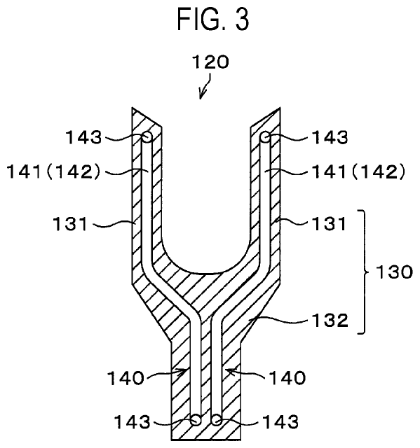

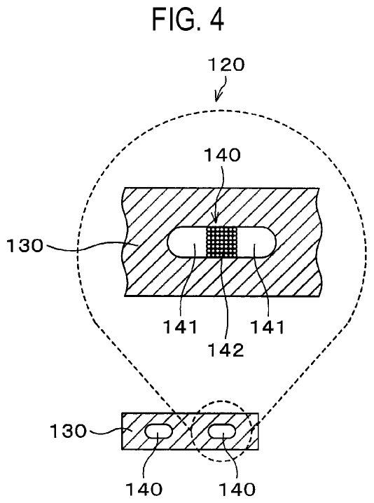

Next, the configuration of the fork 120 will be described. FIG. 3 is a cross-sectional view showing the outline of the internal configuration of the fork 120. FIG. 4 is a longitudinal cross-sectional view showing the outline of the internal configuration of the fork 120.

As shown in FIGS. 3 and 4, the fork 120 has a main body 130 and a heat pipe 140 formed inside the main body 130.

As shown in FIG. 3, the main body 130 is formed in a bifurcated shape and includes two branch portions 131 and a support portion 132 that supports the two branch portions 131, which are integrally formed. The main body 130 is made of a ceramic material. The main body 130 is thin with its thickness of, for example, 2 mm to 3 mm. Pads (not shown) are provided on the upper surface of the main body 130, and the fork 120 attracts and holds the wafer W with these pads.

Heat pipes, for example, two heat pipes 140, are formed inside the main body 130. The two heat pipes 140 are formed inside the two branch portions 131, respectively, and are further formed inside the support portion 132. Each of the heat pipes 140 extends from the tip end of the main body 130 to the base end thereof, that is, from the tip end of the branch portion 131 to the base end of the support portion 132.

The width, number, and arrangement shape of heat pipes 140 are not limited to the present embodiment and can be arbitrarily set. However, if the heat pipes 140 are provided on the entire fork 120, the temperature of the entire fork 120 can be uniformly adjusted.

As shown in FIGS. 3 and 4, each of the heat pipes 140 has a flow path 141 for working fluid, a wick 142 (capillary structure), and a sealing member 143 for sealing the open end of the flow path 141.

The flow path 141 is formed hollow inside the main body 130. The flow path 141 extends from the tip end of the branch portion 131 to the base end of the support portion 132, as described above.

The wick 142 is formed inside the flow path 141 (inside in a side view) and extends from the tip end of the branch portion 131 to the base end of the support portion 132 in the same manner as the flow path 141. The wick 142 is made of the same type of ceramic material as the main body 130. In the present embodiment, the porosity of the wick 142 is higher than the porosity of the main body 130, whereby the wick 142 can play the role of a capillary structure. However, when the porosity of the main body 130 is sufficiently high, the porosity of the wick 142 may be the same as the porosity of the main body 130.

The sealing member 143 is installed at both ends of the open end portion at the tip end of the flow path 141 and the open end portion at the base end of the flow path 141. Although not particularly limited as long as it encloses the working fluid inside the flow path 141, for example, a ceramic component is used for the sealing member 143.

Here, as described above, in the wafer processing system 1 of the present embodiment, after the film forming process is performed on the wafer W in the film forming module 41, the etching process is performed on the wafer W in the etching module 42. In such a case, when the wafer W is loaded/unloaded in/from the film forming module 41 that performs the film forming process of high temperature, the temperature of the fork 120 rises. In this state, when the wafer W is loaded/unloaded in/from the etching module 42 that performs the etching process of low temperature, since the wafer W before the etching process is loaded in the etching module 42 in a state of being excessively heated, the etching rate may deviate from a desired rate. Further, since a temperature difference occurs between the wafer W before the etching process and the wafer W after the etching process, damage or cracks to the wafer W may occur.

In this respect, in the present embodiment, the first arm 101 and the second arm 102 are provided with the temperature adjusting mechanism, and the temperatures of the first arm 101 and the second arm 102 are adjusted and the temperature of the hand part 121 is also adjusted by the temperature adjusting mechanism. Since the heat pipes 140 are formed inside the fork 120, the fork 120 can exchange heat with the hand part 121 via the heat pipes 140. At this time, the fork 120 can be heated and cooled. Then, the temperature of the fork 120 can be brought close to the temperature of the hand part 121, so that the fork 120 can be controlled and adjusted to a desired temperature. In particular, since the heat pipes 140 have high heat transfer performance, the tip end thereof can be adjusted to a desired temperature by adjusting the base end to a desired temperature. Further, in such a case, it is possible to control and adjust the entire fork 120 to a target temperature without having to provide a cooling liquid circulation part or the like on the outside.

Further, since each of the heat pipes 140 extends from the tip end of the main body 130 to the base end of the support portion 132, the heat of the temperature adjusting mechanism is easily transferred to the base end of the heat pipe 140, so that heat exchange between the fork 120 and the hand part 121 can be performed more efficiently. Therefore, the temperature of the fork 120 can be further brought close to the temperature of the hand part 121, so that the temperature of the fork 120 can be adjusted more appropriately.

Since the temperature of the fork 120 can be adjusted in this way, even when processes having different processing temperatures are performed in one wafer processing system 1, the temperature of the fork 120 can be adjusted so that the temperature of the wafer W held by the fork 120 can be adjusted appropriately. As a result, each process on the wafer W can be appropriately performed. Further, it is possible to suppress damage to the wafer W due to a temperature difference in the wafer W.

Further, in the present embodiment, the first arm 101 and the second arm 102 are provided with the temperature adjusting mechanism, but the hand part 121 may also be provided with the temperature adjusting mechanism. In any case, the fork 120 can be adjusted to an appropriate temperature by arranging the base end portion of the heat pipe 140 close to the temperature adjusting mechanism, that is, a heat source. In the related arts, it has been proposed to provide a temperature adjusting mechanism, for example, a heat radiating plate, only on a hand part. However, the temperature adjustment effect of the fork is limited only by the hand part. By providing the heat pipes 140 inside the main body 130 as in the present embodiment, the temperature of the fork 120 can be appropriately adjusted.

Further, since the main body 130 of the fork 120 is made of a ceramic material, it can withstand a low-temperature process in addition to a high-temperature process, and therefore, the fork 120 can handle a wide temperature zone. Moreover, the ceramic material generates less dust, which helps to suppress contamination of the surroundings by particles and the like.

### <Manufacturing Method of Fork>

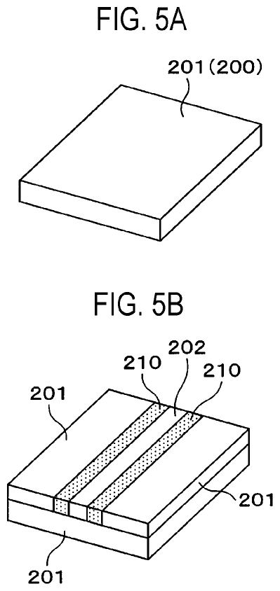

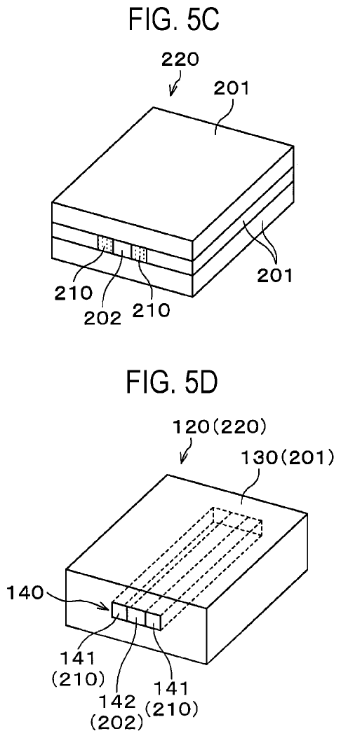

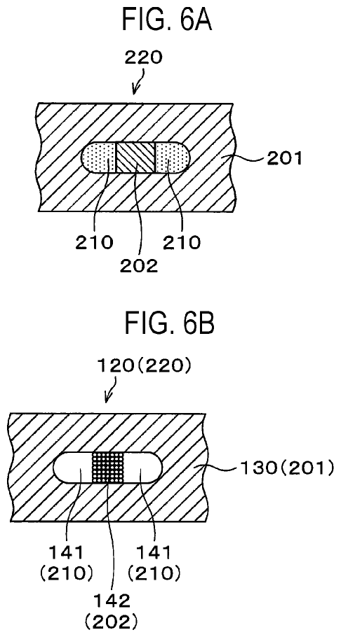

Next, a method of manufacturing the fork 120 will be described. FIGS. 5A to 5D are explanatory views showing a method of manufacturing the fork 120. FIGS. 6A and 6B are explanatory views showing a method of forming the heat pipe 140 in the method of manufacturing the fork 120.

### [Step S1: Raw Body Forming Step]

First, in step S1, a ceramic raw body 220 provided with a support material 210 inside a ceramic material 200 is formed. A method for forming the ceramic raw body 220 is arbitrary, but in the present embodiment, for example, the ceramic material 200 and the support material 210 are laminated to form the ceramic raw body 220 by using a ceramic 3D printing technique.

A fluid slurry in which ceramic powder is dispersed in a liquid as a medium is used for the ceramic material 200. Further, the ceramic material 200 includes a main body ceramic material 201 that functions as the main body 130, and a wick ceramic material 202 that functions as the wick 142. The material of the support material 210 is arbitrary, but a material removed in step S4 to be described later is used for the support material 210.

A known processing device may be used for forming the ceramic raw body 220. For example, the processing device includes an inkjet head capable of ejecting the ceramic material 200 and the support material 210. Then, the ceramic material 200 and the support material 210 are laminated one layer at a time to form a three-dimensional structure.

In step S1, first, as shown in FIG. 5A, the main body ceramic material 201 is laminated.

Next, as shown in FIG. 5B, the main body ceramic material 201, the wick ceramic material 202, and the support material 210 are further laminated. The support material 210 is removed in step S4 to be described later to form the flow path 141 of the heat pipe 140. Therefore, the support material 210 is formed at a position at which the flow path 141 is formed inside of the main body ceramic material 201 in a side view.

Since the wick ceramic material 202 functions as the wick 142, it is formed inside the support material 210 in a side view. Further, the wick ceramic material 202 has a porosity higher than the porosity of the main body ceramic material 201. For example, the porosity of each of the ceramic materials 201 and 202 can be adjusted by adjusting the composition of the slurry used in the main body ceramic material 201 and the wick ceramic material 202. In this way, since the porosity of the wick ceramic material 202 is higher than the porosity of the main body ceramic material 201, the wick 142 can play the role of a capillary structure. However, as described above, when the porosity of the main body ceramic material 201 is sufficiently high, the porosity of the wick ceramic material 202 may be the same as the porosity of the main body ceramic material 201.

Next, as shown in FIGS. 5C and 6A, the main body ceramic material 201 is further laminated. Then, the ceramic raw body 220 is formed. That is, the ceramic raw body 220 has a structure in which the support material 210 and the wick ceramic material 202 are provided inside the main body ceramic material 201.

Here, the thickness of the fork 120 (the main body 130) is as thin as 2 mm to 3 mm, for example. It is difficult to cut the inside of such a thin ceramic plate after firing (heat-treating) to form a fine structure, and it is difficult to form a heat pipe for temperature adjustment inside the fork by the method of the related arts. In other words, if the heat pipe is to be formed inside the fork, the thickness of the fork will increase.

In this respect, in the present embodiment, in the step S1, a fine structure of the support material 210 and the wick ceramic material 202 can be formed inside the main body ceramic material 201. That is, it is possible to form a fine structure for forming the heat pipe 140 inside the main body 130 while keeping the thickness of the main body 130 of the fork 120 thin.

Further, it is conceivable to embed a metal heat pipe or a refrigerant pipe in the thin ceramic plate, but as compared with such a case, when a fine structure is formed in the main body 130 made of a ceramic material as in the present embodiment, it is possible to suppress a decrease in mechanical strength of the ceramic material. Furthermore, when the metal heat pipe or the refrigerant pipe is embedded in the thin ceramic plate, cracks and dust may occur due to a difference in thermal expansion between ceramic and metal, and the temperature controllability may deteriorate due to thermal resistance at a joint. However, in the present embodiment, the occurrence of such situations can be suppressed.

The method of forming the ceramic raw body 220 in step S1 is not limited to the above embodiment. For example, the ceramic raw body 220 may be formed by firing a polymer polymerized while forming a three-dimensional shape in a liquid. Alternatively, a ceramic slurry may be inkjet-printed to form the ceramic raw body 220.

### [Step S2: Firing Step]

Next, in step S2, the ceramic raw body 220 is fired. At this time, the ceramic raw body 220 is fired under the humidity and firing conditions according to a slurry of the ceramic material 201. A known heating device may be used for firing the ceramic raw body 220.

### [Step S3: Outer Shape Finishing Step]

Next, in step S3, the outer shape of the ceramic raw body 220 is cut, and the surface thereof is polished and finished. A known grinding device may be used for finishing the outer shape of the ceramic raw body 220. In this way, the ceramic raw body 220 is formed.

[Step S4: Main body Forming Step (Flow Path Forming Step)]

Next, in step S4, the main body 130 is formed. As shown in FIGS. 5D and 6B, the support material 210 is removed from the ceramic raw body 220. A method of removing the support material 210 can be arbitrarily selected. For example, when the support material 210 is a resin, the support material 210 is removed by raising the temperature of the support material 210 and sublimating it in a decompression atmosphere. Alternatively, an acid gas may be supplied to dissolve the support material 210. Then, the flow path 141 is formed inside the main body ceramic material 201, thereby forming the main body 130.

### [Step S5: Working Fluid Enclosing Step]

Next, in step S5, a working fluid is supplied to and enclosed in the inside of the flow path 141. A method of supplying the working fluid can be arbitrarily selected.

### [Step S6: Sealing Step]

Next, in step S6, the sealing member 143 is provided at the open end of the flow path 141 to seal the flow path 141. For example, the sealing member 143, which is a ceramic component, is attached to the open end by brazing or the like. In this way, the heat pipe 140 is formed inside the main body 130, and the fork 120 is manufactured.

According to this embodiment, even when the main body 130 of the fork 120 is a thin ceramic material, the heat pipe 140 can be formed inside the main body 130.

Here, conventionally, as disclosed in, for example, Japanese Patent No. 4,057,158, there is a technique of providing a heat pipe as a cooling flow path in which a refrigerant is enclosed inside a metal fork (transfer arm). In this technique, since the fork is made of metal, it is easy to process the fork, and there is no difference in thermal expansion between the fork and the heat pipe. Therefore, even when the fork is thin, the heat pipe can be provided inside the fork.

However, the metal fork has a limited use temperature zone. In this respect, in the present embodiment, since a ceramic material is used for the main body 130 of the fork 120, it can withstand the low-temperature process in addition to the high-temperature process, and therefore, the fork 120 can be used in a wide temperature zone. In the first place, the fork disclosed in Japanese Patent No. 4,057,158 is used in the normal pressure atmosphere, and it is not assumed that the fork is used in a wide temperature zone under a decompression atmosphere as in the present embodiment.

On the other hand, when the thin ceramic material is used for the main body 130 as in the present embodiment, it is difficult to form a fine structure by cutting the inside after firing the thin ceramic plate in the related art as described above, and therefore, it is difficult to form a heat pipe formed of the fine structure. Further, when the metal heat pipe is embedded in the thin ceramic plate, a difference in thermal expansion between ceramic and metal may occur, which may cause cracks or dust. In this respect, in the present embodiment, even when the main body 130 of the fork 120 is the ceramic thin material, the heat pipe 140 can be formed by forming the fine structure inside the main body 130 by performing the above steps S1 to S6.

### OTHER EMBODIMENTS

Here, in the heat pipe 140, the inner surface of the flow path 141 is a ceramic material which is the main body 130, and since the ceramic material is a porous body, the enclosed working fluid may penetrate into the outside of the flow path 141, that is, the inside of the main body 130. For example, when the porosity of the main body 130 is high, the working fluid may penetrate into the inside of the main body 130, which may deteriorate the function of the heat pipe 140. Therefore, the following three countermeasures can be taken.

### [First Countermeasure]

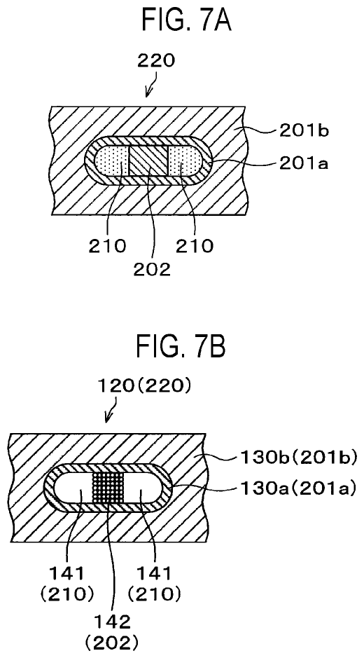

The first countermeasure to suppress leakage of the working fluid is to reduce the porosity of the outer wall of the flow path 141. FIGS. 7A and 7B are explanatory views showing a method of forming the heat pipe 140 in the first countermeasure.

When the ceramic raw body 220 is formed in step S1, an inner main body ceramic material 201a and an outer main body ceramic material 201b are laminated as the main body ceramic material 201, as shown in FIG. 7A. The inner main body ceramic material 201a is laminated around the wick ceramic material 202 and the support material 210 and functions as an outer wall of the flow path 141. The outer main body ceramic material 201b is further laminated around the inner main body ceramic material 201a.

The porosity of the inner main body ceramic material 201a is lower than the porosity of the outer main body ceramic material 201b. For example, the porosity of each of the main body ceramic materials 201a and 201b can be adjusted by adjusting the composition of the slurry used for the inner main body ceramic material 201a and the outer main body ceramic material 201b.

After that, after firing the ceramic raw body 220 in step S2 and then finishing the outer shape of the ceramic raw body 220 in step S3, the support material 210 is removed in step S4, as shown in FIG. 7B. Then, the flow path 141 is formed inside the main body ceramic material 201 to form the main body 130. The main body 130 includes an inner main body 130a constituting the outer wall of the flow path 141 and an outer main body 130b outside the inner main body 130a.

In such a case, since the porosity of the inner main body 130a is lower than the porosity of the outer main body 130b, leakage of the working fluid from the flow path 141 in the heat pipe 140 can be suppressed.

### [Second Countermeasure]

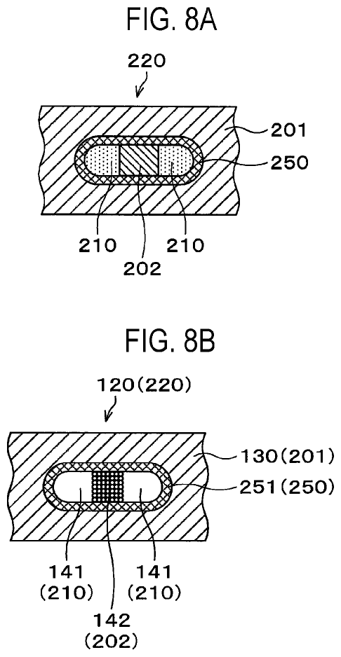

The second countermeasure to suppress the leakage of the working fluid is to use a material different from the ceramic material for the outer wall of the flow path 141. FIGS. 8A and 8B are explanatory views showing a method of forming the heat pipe 140 in the second countermeasure.

When the ceramic raw body 220 is formed in step S1, an outer wall material 250 is laminated around the wick ceramic material 202 and the support material 210, and the main body ceramic material 201 is further laminated around the outer wall material 250, as shown in FIG. 8A. A material, for example, quartz, having a lower porosity than that of the main body ceramic material 201 is used for the outer wall material 250 and functions as the outer wall portion of the flow path 141.

After that, after firing the ceramic raw body 220 in step S2 and then finishing the outer shape of the ceramic raw body 220 in step S3, the support material 210 is removed in step S4, as shown in FIG. 8B. Then, the flow path 141 having an outer wall portion 251 (the outer wall material 250) is formed inside the main body ceramic material 201 to form the main body 130.

In such a case, since the porosity of the outer wall portion 251 is low, leakage of the working fluid from the flow path 141 in the heat pipe 140 can be suppressed.

### [Third Countermeasure]

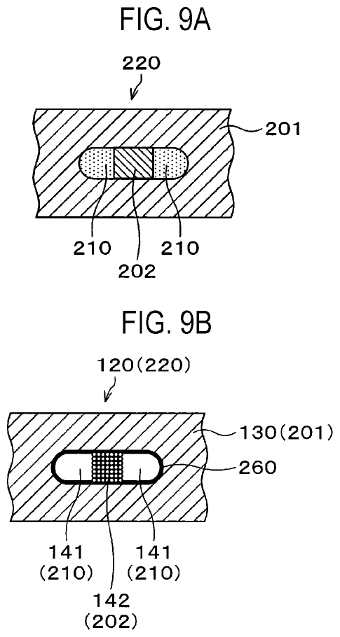

The third measure to suppress the leakage of the working fluid is to form a metal film on the inner surface of the flow path 141. FIGS. 9A and 9B are explanatory views showing a method of forming the heat pipe 140 in the third countermeasure.

Steps S1 to S3 are sequentially performed to form the ceramic raw body 220, as shown in FIG. 9A. After that, in step S4, after removing the support material 210 as shown in FIG. 9B, a metal film 260 is formed on the inner surface of the flow path 141. A method for forming the metal film 260 is arbitrary, but for example, a metal material is deposited on the inner surface of the flow path 141 to form the metal film 260.

In such a case, the metal film 260 can suppress the leakage of the working fluid from the flow path 141 in the heat pipe 140.

### OTHER EMBODIMENTS

In the above embodiment, the case where the temperature of the fork 120 is adjusted when the high-temperature film forming process and the low-temperature etching process are sequentially performed in the wafer processing system 1 has been described, but the fork 120 can be adjusted to an appropriate temperature even when the low-temperature process and the high-temperature process are sequentially performed.

Further, the fork 120 can also be applied to a wafer transfer device of a wafer processing system that performs a single process. Even in the case of the single process, since the temperatures at the start of the process and the temperature at the end of the process are different from each other, there is the same problem as when plural processes are performed. In this respect, in the present embodiment, since the temperature of the wafer W can be appropriately adjusted by adjusting the temperature of the fork 120, the single process can be stably performed.

Further, although the fork 120 is used in the wafer transfer device 50 used in the decompression atmosphere in the above embodiment, it may be applied to a wafer transfer device used in the normal pressure atmosphere.

In the fork 120 of the above embodiment, the heat pipe 140 formed inside the main body 130 is of an enclosure type in which the working fluid is enclosed, but the type of the heat pipe 140 is not limited thereto. For example, the heat pipe 140 may be of a type that circulates the working fluid with the outside.

The embodiments disclosed this time should be considered to be exemplary in all respects and not restrictive. The above embodiments may be omitted, replaced, and changed in various forms without departing from the scope of the accompanying claims and their gist.

According to the present disclosure in some embodiments, it is possible to appropriately adjust the temperature of a substrate holder in a substrate transfer device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate holder that holds a substrate and is installed in a device for transferring the substrate, comprising:
a ceramic main body; and
a heat pipe including a flow path of a working fluid formed inside the main body.

2. The substrate holder of claim 1, wherein the heat pipe includes a ceramic wick formed inside the flow path.

3. The substrate holder of claim 2, wherein a porosity of the wick is higher than a porosity of the main body.

4. The substrate holder of claim 3, wherein the heat pipe includes a sealing member installed at an open end of the flow path.

5. The substrate holder of claim 4, wherein the main body includes:
an inner main body that constitutes an outer wall of the flow path; and
an outer main body outside the inner main body,
wherein a porosity of the inner main body is lower than a porosity of the outer main body.

6. The substrate holder of claim 5, wherein the heat pipe extends from a tip end of the main body to a base end of the main body.

7. The substrate holder of claim 1, wherein the flow path includes an outer wall portion,
wherein a material of the outer wall portion and a material of the main body are different from each other.

8. The substrate holder of claim 1, further comprising: a metal film formed on an inner surface of the flow path.

9. The substrate holder of claim 1, wherein the heat pipe extends from a tip end of the main body to a base end of the main body.

10. A substrate transfer device that transfers a substrate to and from processing apparatuses under a decompression atmosphere, comprising:
a substrate holder configured to hold the substrate; and
a moving mechanism configured to move the substrate holder at least in a horizontal direction,
wherein the substrate holder includes:
a ceramic main body; and
a heat pipe including a flow path of a working fluid formed inside the main body.

11. The substrate transfer device of claim 10, wherein the moving mechanism includes a temperature adjusting mechanism.

12. The substrate transfer device of claim 11, wherein the heat pipe extends from a tip end of the main body to a base end of the main body, and
wherein a heat of the temperature adjusting mechanism is transferred to a base end of the heat pipe.

13. A method of manufacturing a substrate holder that holds a substrate and is installed in a device for transferring the substrate, comprising:
(a) forming a ceramic raw body including a support material inside a ceramic material;
(b) forming a ceramic main body by removing the support material to form a flow path of a working fluid inside the ceramic material; and
(c) forming a heat pipe by enclosing the working fluid inside the flow path.

14. The method of claim 13, wherein (a) includes:
forming the ceramic raw body by laminating the ceramic material and the support material;
firing the ceramic raw body; and
finishing an outer shape of the ceramic raw body.

15. The method of claim 14, wherein the ceramic material includes:
a main body ceramic material that functions as the main body; and
a wick ceramic material that functions as a wick of the heat pipe,
wherein in (a), the wick ceramic material is installed inside the support material.

16. The method of claim 15, wherein a porosity of the wick ceramic material is higher than a porosity of the main body ceramic material.

17. The method of claim 16, wherein in (c), after the working fluid is enclosed inside the flow path, a sealing member is installed at an end portion of the flow path.

18. The method of claim 17, wherein the main body includes:
an inner main body that constitutes an outer wall of the flow path; and
an outer main body outside the inner main body,
wherein a porosity of the ceramic material of the inner main body is lower than a porosity of the ceramic material of the outer main body.

19. The method of claim 13, wherein in (a), an outer wall material of a type different from the ceramic material is laminated around the support material, and
wherein in (b), the support material is removed to form the flow path inside the outer wall material.

20. The method of claim 13, wherein after (b), a metal film is formed on an inner surface of the flow path.
